(19) United States
(12) Patent Application Publication
(10) Pub. No.: US 2018/0090300 A1
(43) Pub. Date: Mar. 29, 2018

(54) Diffuser With Corner HCG

(71) Applicant: Applied Materials, Inc., Santa Clara, CA (US)

(72) Inventors: Lai ZHAO, Campbell, CA (US); Gaku FURUTA, Sunnyvale, CA (US); Soo Young CHOI, Fremont, CA (US); Beom Soo PARK, San Jose, CA (US)

(21) Appl. No.: 15/277,774

(22) Filed: Sep. 27, 2016

(51) Int. Cl. H01J 37/32; C23C 16/455

(52) U.S. Cl. CPC H01J 37/3244; H01J 37/32596; H01J 2237/3321; H01J 2237/3323; C23C 16/45563

(57) ABSTRACT

The present disclosure generally relates to a gas distribution plate for ensuring deposition uniformity. The gas distribution plate has multiple concave portions on the downstream side to ensure uniform deposition in corner regions of the processing chamber.

### BACKGROUND

### Field

Embodiments of the present invention generally relate to a gas distribution plate for a chemical vapor deposition (CVD) system designed to compensate for deposition non-uniformity.

### Description of the Related Art

Plasma enhanced chemical vapor deposition (PECVD) is a deposition method that has long been used to deposit may films onto semiconductors substrates. PECVD has recently been used to deposit films on large area substrates such as solar panel substrates, flat panel display substrates, and large area thin film transistor substrates. Market forces continue to drive down the cost of flat panel displays while increasing the size of the substrate. Substrate sizes greater than 1 square meter are not uncommon in flat panel display processes.

Gas distribution plates may be used to ensure an even distribution of the deposition plasma throughout the processing chamber. An even distribution of plasma may aid in film uniformity across the substrate. With increasing substrate size, however, obtaining an even distribution of plasma within the processing chamber can be a challenge.

Therefore, there is a need in the art for an improved gas distribution plate.

### SUMMARY

The present disclosure generally relates to a gas distribution plate for ensuring deposition uniformity. In one embodiment, the plate comprises a diffuser body has an upstream surface, a downstream surface, four sides and four corners, the diffuser body having a plurality of gas passages extending from the upstream surface to the downstream surface, each gas passage includes a hollow cathode cavity: a center hollow cathode cavity is disposed near the center of the diffuser body; a corner hollow cathode cavity is disposed near the corner of the diffuser body, the corner hollow cathode cavity is larger than the center hollow cathode cavity; a first hollow cathode cavity is disposed at a location between the center hollow cathode cavity and the corner hollow cathode cavity, the first hollow cathode cavity is greater in size than the center hollow cathode cavity and less in size than the corner hollow cathode cavity; and a second hollow cathode cavity is disposed at a location between the corner hollow cathode cavity and the first hollow cathode cavity, the second hollow cathode cavity is less in size than the corner hollow cathode cavity and less in size than the first hollow cathode cavity.

In another embodiment, a gas distribution plate comprises a diffuser body having an upstream surface, a downstream surface, four sides and four corners, the diffuser body having a plurality of gas passages extending from the upstream surface to the downstream surface, each gas passage includes a hollow cathode cavity: a center hollow cathode cavity is disposed near the center of the diffuser body; a side hollow cathode cavity is disposed near the side of the diffuser body, the side hollow cathode cavity is larger than the center hollow cathode cavity; a first hollow cathode cavity is disposed at a location between the center hollow cathode cavity and the side hollow cathode cavity, the first hollow cathode cavity is greater in size than the center hollow cathode cavity and less in size than the side hollow cathode cavity; and a second hollow cathode cavity is disposed at a location between the side hollow cathode cavity and the first hollow cathode cavity, the second hollow cathode cavity is less in size than the side hollow cathode cavity and less in size than the first hollow cathode cavity.

In another embodiment, plasma processing chamber comprises a chamber body; a substrate support disposed within the chamber body; and a gas distribution plate disposed within the chamber body and facing the substrate support, the gas distribution plate comprising: a diffuser body having an upstream surface, a downstream surface, four sides and four corners, the diffuser body having a plurality of gas passages extending from the upstream surface to the downstream surface, each gas passage includes a hollow cathode cavity: a center hollow cathode cavity is disposed near the center of the diffuser body; a corner hollow cathode cavity is disposed near the corner of the diffuser body, the corner hollow cathode cavity is larger than the center hollow cathode cavity; a first hollow cathode cavity is disposed at a location between the center hollow cathode cavity and the corner hollow cathode cavity, the first hollow cathode cavity is greater in size than the center hollow cathode cavity and less in size than the corner hollow cathode cavity; and a second hollow cathode cavity is disposed at a location between the corner hollow cathode cavity and the first hollow cathode cavity, the second hollow cathode cavity is less in size than the corner hollow cathode cavity and less in size than the first hollow cathode cavity.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic cross sectional view of a processing chamber according to one embodiment.

FIG. 2 is a schematic cross sectional view of a gas passage.

FIG. 3 is a top view of a gas distribution plate.

FIG. 4 is a schematic cross sectional view taken along line A-A of FIG. 3.

FIG. 5 is a schematic cross sectional view taken along line B-B of FIG. 3.

FIG. 6 is a schematic cross sectional view taken along line C-C of FIG. 3.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure will be illustratively described below in reference to a PECVD system configured to process large area substrates such as a PECVD system available from AKT, a division of Applied Materials, Inc., Santa Clara, Calif. However, it is to be understood that the disclosure has utility in other system configurations such as those utilized to process small or round substrates. The disclosure also has utility in processing systems manufactured by other manufacturers.

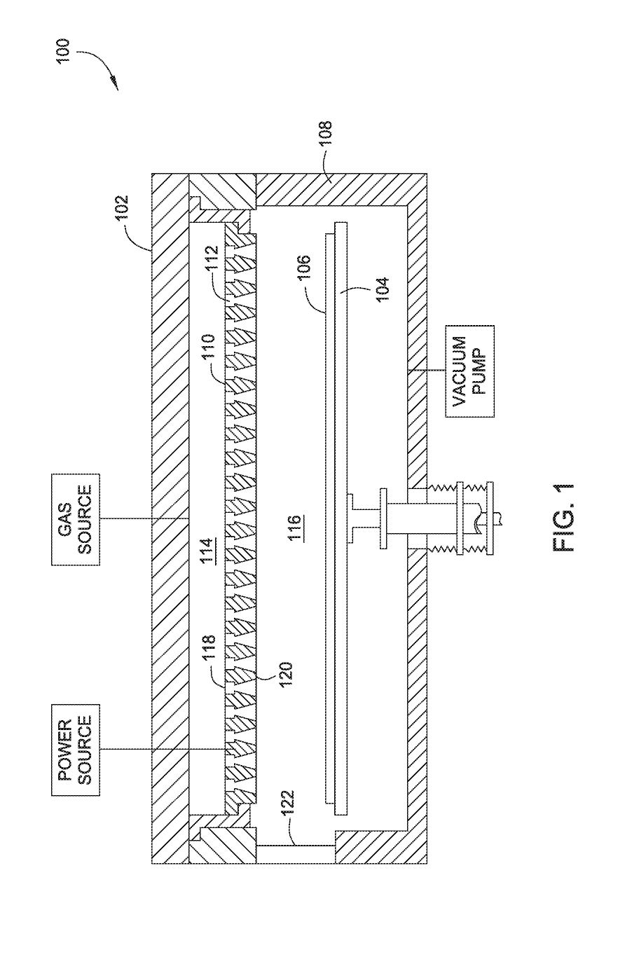

FIG. 1 is a schematic cross sectional view of a processing chamber 100 according to one embodiment. The processing chamber 100 comprises chamber body having a lid 102 and walls 108. Within at least one wall 108, one or more slit valve openings 122 may be present to permit insertion of substrates 106 to the processing space 116 and removal of substrates 106 from the processing space 116. The processing space 116 may be bound by the slit valve opening 122, chamber walls 108, substrate 106, and gas distribution plate 110. In one embodiment, the gas distribution plate 110 may be biased by a power source. The substrate 106 may be disposed on a substrate support 104 that may translate up and down to raise and lower the substrate 106 as necessary.

Gas may be introduced to an area between the gas distribution plate 110 and the lid 102 called the plenum 114. The gas may be evenly distributed within the plenum 114 due to the presence of gas passages 112 that extend from an upstream side 118 of the diffuser plate through to the downstream side 120.

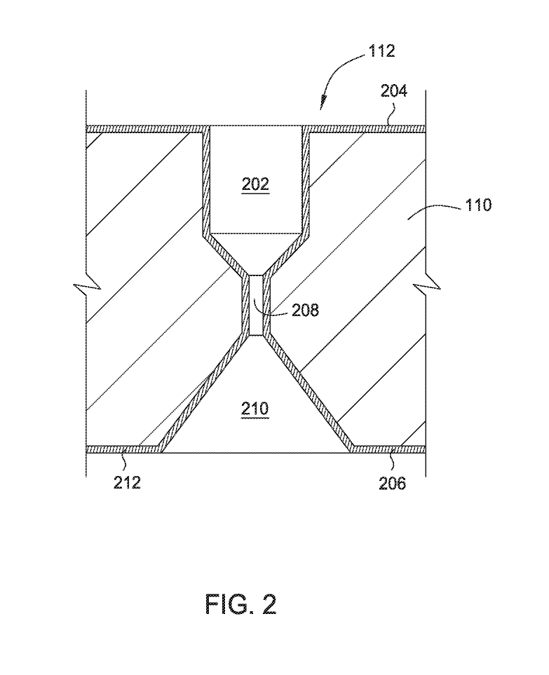

FIG. 2 is a schematic cross sectional view of a gas passage 112. The gas passage 112 includes an upper portion 202 extending from the upstream surface 204 of the gas distribution plate 110. The upstream surface 204 faces the lid 102 and the downstream surface 206 faces the substrate 106. The gas passage also has a choke 208 or pinch point and a hollow cathode cavity (HCC) 210. The choke 208 is the narrowest point within the gas passage 112 and hence the location that controls the gas flow through the gas passage 112. The choke 208 is generally of the same length and width for every choke 208 in the gas distribution plate 110 however, it is understood that some mechanical tolerances may cause slight variations. In one embodiment, the upper portion 202 is not present, but rather, the choke 208 extends to the upstream surface 204.

The HCC 210 may be cone or cylinder shaped or a combination of both. The HCC 210 is sized to permit ignition of plasma within the HCC 210. In other words, a plasma may be ignited within the gas distribution plate 110 itself in addition to within the processing space 116. By igniting the plasma within the HCC 210, the shape of the plasma may be controlled because the shape and/or size of the HCC 210 affect the shape and/or intensity of the plasma within the chamber 100.

Silicon nitride is one film that may be deposited in a PECVD chamber using silane gas. Silicon nitride can be used as a passivation layer, a gate insulator layer, a buffer layer, an interlayer and even as a barrier layer for amorphous silicon thin film transistors (TFTs), low temperature polysilicon TFTs and active matrix organic light emitting diode (OLED) displays. Additionally, silicon nitride may be used as a barrier layer in thin film encapsulation applications. The thickness and uniformity of the nitride layer has a significant effect on the device performance, such as the uniformity of the drain current (i.e., mobility) and the threshold voltage in the TFTs.

Because the TFT device performance is sensitive to film thickness variations, thickness uniformity control has gained interest among engineers. Uniformity expectations can range from up to 3 percent for amorphous silicon to 4 percent for silicon oxides to as much as 5 percent for silicon nitride.

Uniformity within a substrate is not the only area of concern through. run to run uniformity is also closely monitored. Processing chambers are periodically cleaned, and run to run uniformity of 2 percent to 3 percent is expected in most scenarios with as many as eight processed occurring prior to cleaning.

Silicon nitride deposition can be challenging in large area substrate processing chambers. The deposition rate of silicon nitride films can be higher at the corners of the substrate and edges of the substrate within a single cycle prior to cleaning because the silicon nitride film can accumulate at the corner and edge of the gas distribution plate. The accumulation of the silicon nitride may be referred to as the dielectric effect and enhances the local plasma density by changing the surface electron emission conditions and thus increases the deposition rate of the dielectric film in the next deposition due to the locally enhanced plasma. The dielectric effect deteriorates the uniformity of the silicon nitride process, for examples from about 3 percent to about 6 percent mainly from the corner high deposition rate peaks and changes the average deposition rate up to 6 percent. If the gas distribution plate is used for longer term production, the situation may become worse with additional dielectric accumulation occurring due to the interaction of the cleaning gas with the gas distribution plate to produce aluminum fluoride.

Many attempts to correct for the deposition uniformity have occurs such as reducing the plasma power (leads to compromised film quality), refurbishing the gas distribution plate more frequently, adjusting the deposition time within one clean cycle, and inserting conductive seasoning (such as amorphous silicon), but no option to date can solve the within clean cycle variation and the uniformity variation from the corner of the gas distribution plate to the center. Anodization has been used in the past, but simply adding an anodized layer to a bare aluminum gas distribution plate results in silicon nitride non-uniformity at the corners because the silicon nitride coating is a dielectric coating at the corner.

To solve the uniformity issues, a permanent dielectric layer (i.e., an anodization layer) of material such as A1₂O₃, Y₂O₃ or other dielectric material can survive a fluorine based cleaning environment, is formed over all exposed surfaces of the gas distribution plate 110. The anodization layer 212 can avoid additional dielectric effect in subsequent depositions and thus run to run uniformity degradation due to the dielectric effect can be prevented. The anodization layer 212 may be formed to a surface roughness of about 1 μm to about 20 μm with a total thickness of about 1 μm to about 20 μm to reduce the absorption of fluorine atoms during cleaning and to minimize the risk of the anodization layer 212 cracking and peeling. Additionally, a hollow cathode gradient (HCG) not only at the center of the gas distribution plate, but also at the edges and corner areas pushes down the high deposition rate peaks and the corners and edges.

The anodization and corner HCG improves the thickness uniformity of the initial deposition by pushing down the corner high deposition rate peaks, and the run to run deposition rate uniformity deterioration is pushed down as well by providing a permanent high quality dielectric film (i.e., the anodization layer 212). The corner HCG and anodization does not compromise the process conditions for better uniformity, does not require frequent refurbishment (which would be needed for base aluminum gas distribution plates to recover silicon nitride uniformity), does not require an adjustment of the deposition time from one deposition to the next, does not require conductive seasoning that would affect substrate throughput, and does not add initial thick silicon nitride seasoning that would impact particle performance.

It has surprisingly found that corner HCG along with anodization controls the deposition rate variation in silicon nitride processes to below 1 percent within an eight substrate cycle, and a thickness uniformity of about 2.9 percent to about 3.5 percent, which is significantly better than a bare aluminum gas distribution plate. There is also a 6 percent deposition rate increase within a 9 substrate clean cycle and around 3.8 percent to about 6.3 percent uniformity. It is to be understood that the anodization and corner HCG may be applicable to other film deposition processed such as silicon oxynitride.

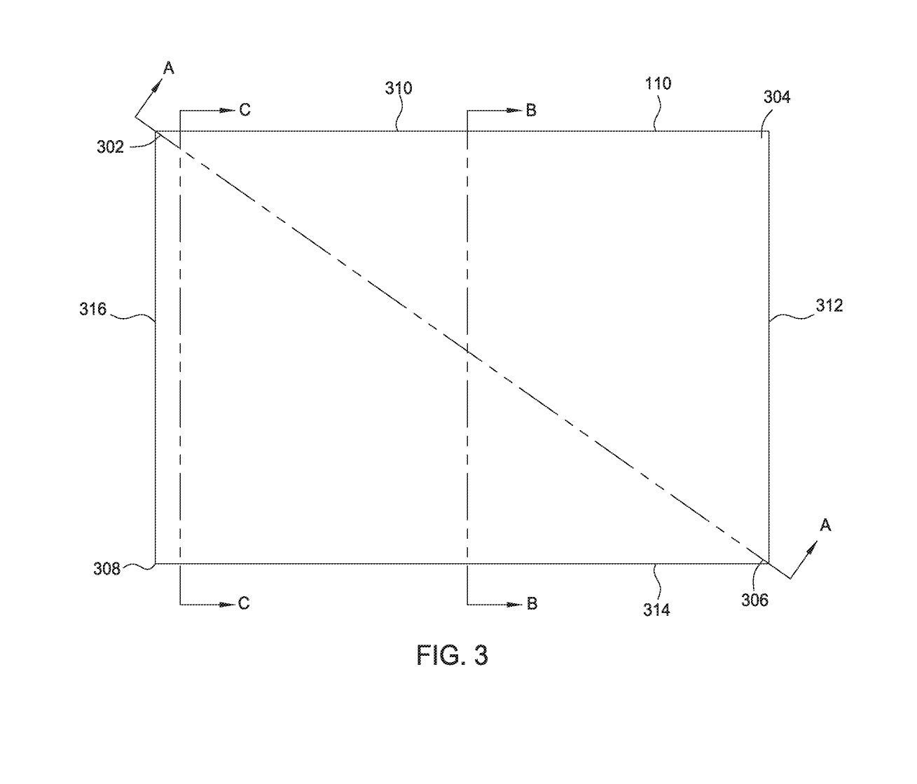

FIG. 3 is a top view of a gas distribution plate 110 looking at the upstream side 204. The gas passages 112 have not been shown for clarity. FIG. 3 shows the gas distribution plate 110 to have a first corner 302, a second corner 304, a third corner 306 and a fourth corner 308. Additionally, the gas distribution plate 110 has a first side 310, a second side 312, a third side 314 and a fourth side 316.

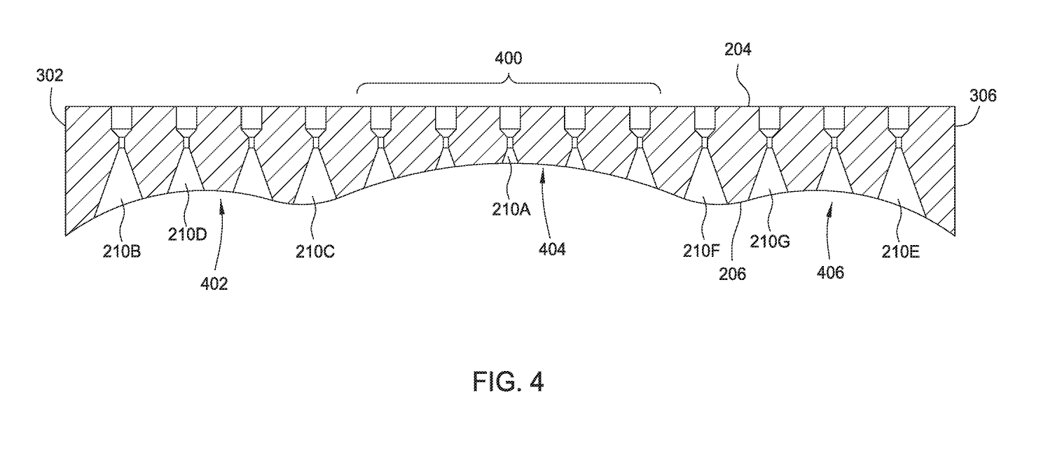

FIG. 4 is a schematic cross sectional view taken along line A-A of FIG. 3. The anodization layer is not shown for clarity but it is understood that the anodization layer 212 is present. In FIG. 4, the downstream surface 206 has a plurality of concave portions 402, 404, 406 corresponding to the first corner 302 area, center area 400 and third corner 306 area. As shown in FIG. 4, the HCCs 210 have different sizes at different locations along the cross section. For example, a gas passage 112 near the center of the center area 400 of the gas distribution plate 110 has a HCC 210A of a first size while a gas passage 112 near the first corner 302 has a HCC 210B of a second size that is greater than the first size. In between the first corner 302 and the center area 400, there is another gas passage 112 that has an HCC 210C of a third size that is both greater than the first size, but also smaller than the second size. In between the gas passage 112 with the HCC 210C of the third size and the gas passage 112 near the corner 302 with the HCC 210B is another gas passage 112 with an HCC 210D of a fourth size that is both smaller than the HCC 210B and HCC 210C.

The other half of the cross section of FIG. 4 is a mirror image of the first half. Specifically, a gas passage 112 near the third corner 306 has a HCC 210E of a fifth size that is greater than the first size. In between the third corner 306 and the center area 400, there is another gas passage 112 that has an HCC 210F of a sixth size that is both greater than the first size, but also smaller than the fifth size. In between the gas passage 112 with the HCC 210F of the third size and the gas passage 112 near the corner 302 with the HCC 210E is another gas passage with an HCC 210G of a seventh size that is both smaller than the HCC 210E and HCC 210F.

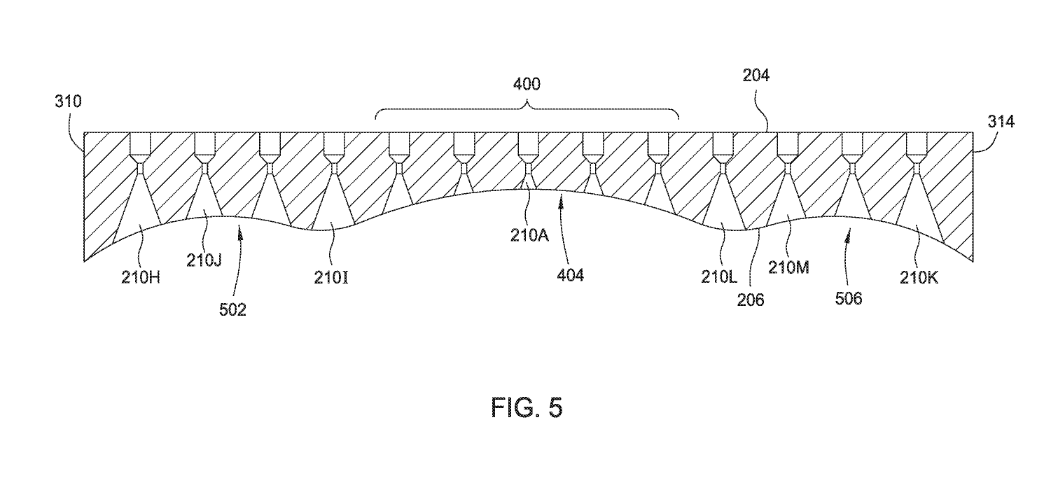

FIG. 5 is a schematic cross sectional view taken along line B-B of FIG. 3. Similar to FIG. 4, there are three concave portions 502, 404, 506 corresponding to the first side 310 area, the center area 400 and the third side 314 area. As shown in FIG. 5, the HCCs 210 have different sizes at different locations along the cross section. For example, a gas passage 112 near the first side 310 has a HCC 210H of an eighth size that is greater than the first size of HCC 210A. In between the first side 310 and the center area 400, there is another gas passage 112 that has an HCC 2101 of a ninth size that is both greater than the first size, but also smaller than the eighth size. In between the gas passage 112 with the HCC 2101 of the ninth size and the gas passage 112 near the side 310 with the HCC 210H is another gas passage 112 with an HCC 210J of a tenth size that is both smaller than the HCC 210H and HCC 210I.

The other half of the cross section of FIG. 5 is a mirror image of the first half. Specifically, a gas passage 112 near the third side 314 has a HCC 210K of an eleventh size that is greater than the first size. In between the third side 314 and the center area 400, there is another gas passage 112 that has an HCC 210L of a twelfth size that is both greater than the first size, but also smaller than the eleventh size. In between the gas passage 112 with the HCC 210L of the eleventh size and the gas passage 112 near the side 314 with the HCC 210K is another gas passage with an HCC 210M of a thirteenth size that is both smaller than the HCC 210K and HCC 210L.

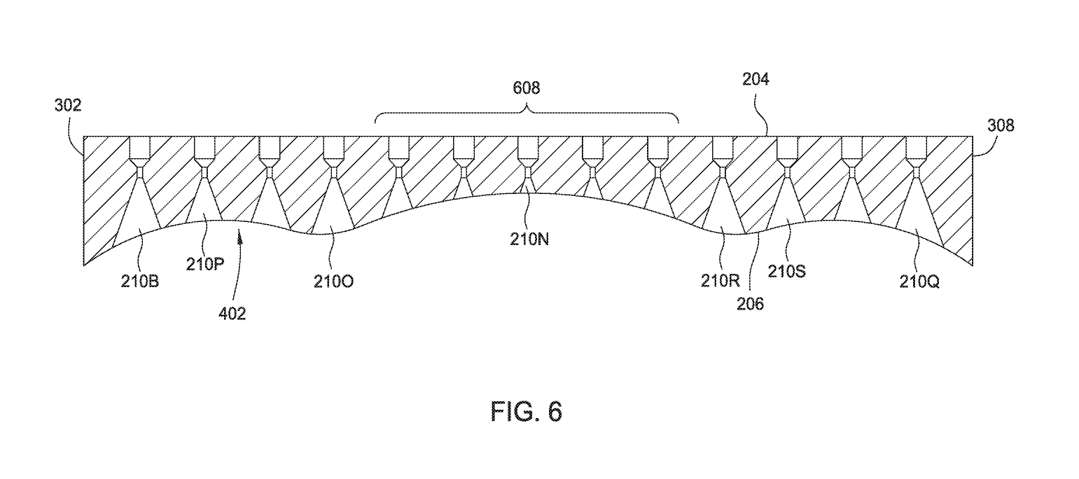

FIG. 6 is a schematic cross sectional view taken along line C-C of FIG. 3. Similar to FIGS. 4 and 5, there are three concave portions 402, 604, 606 corresponding to the first corner 302 area, a center area 608 of the fourth side 316 and the fourth corner 308 area. As shown in FIG. 6, the HCCs 210 have different sizes at different locations along the cross section. For example, a gas passage 112 near the center area 608 of the fourth side 316 has a HCC 210N of a fourteenth size that is less than the second size of HCC 210B. In between the first corner 302 and the center area 608, there is another gas passage 112 that has an HCC 210O of a fifteenth size that is both greater than the fourteenth size, but also smaller than the second size. In between the gas passage 112 with the HCC 210O of the fifteenth size and the gas passage 112 near the corner 302 with the HCC 2106 is another gas passage 112 with an HCC 210P of a sixteenth size that is both smaller than the HCC 210B and HCC 210O.

The other half of the cross section of FIG. 6 is a mirror image of the first half. Specifically, a gas passage 112 near the fourth corner 308 has a HCC 210Q of a seventeenth size that is greater than the fourteenth size. In between the fourth corner 308 and the center area 608, there is another gas passage 112 that has an HCC 210R of an eighteenth size that is both greater than the fourteenth size, but also smaller than the seventeenth size. In between the gas passage 112 with the HCC 210R of the seventeenth size and the gas passage 112 near the corner 308 with the HCC 210Q is another gas passage 112 with an HCC 210S of a nineteenth size that is both smaller than the HCC 210R and HCC 210Q.

In referring to the “size” of the various HCCs 210, it is to be understood that the “size” may refer to the volume of the HCC 210 or to the diameter of the HCC at the downstream surface 206.

When referring to the various concave portions shown along the cross sectional lines for FIG. 4-6, it is to be understood that there would be a concave area adjacent each side 310, 312, 314, 316 and a concave area adjacent each corner 302, 304, 306, 308. Additionally, there would be a concave area in the center area 400. Hence, in one embodiment, it is contemplated that there are nine separate and distinct concave portions on the downstream side of the gas distribution plate 110.

By utilizing multiple HCGs on the downstream side of a gas distribution plate, uniform deposition is possible within a single substrate deposition process. With the addition of an anodized coating on the gas distribution plate, the uniform deposition may be extended to not only a single substrate, but to all of the substrates within a cycle. As such, the number of substrate that may be processed within a single cleaning cycle may be increased and substrate throughput increased. The multiple HCG gradients and the anodization coating compensates for deposition non-uniformity not only in a single substrate, but within an entire cycle of substrates.

While the foregoing is directed to embodiments of the present disclosure, other and further embodiments of the disclosure may be devised without departing from the basic scope thereof, and the scope thereof is determined by the claims that follow.

What is claimed is:

1. A gas distribution plate, comprising:
a diffuser body having an upstream surface, a downstream surface, four sides and four corners, the diffuser body having a plurality of gas passages extending from the upstream surface to the downstream surface, each gas passage includes a hollow cathode cavity:
a center hollow cathode cavity is disposed near the center of the diffuser body;
a corner hollow cathode cavity is disposed near the corner of the diffuser body, the corner hollow cathode cavity is larger than the center hollow cathode cavity;
a first hollow cathode cavity is disposed at a location between the center hollow cathode cavity and the corner hollow cathode cavity, the first hollow cathode cavity is greater in size than the center hollow cathode cavity and less in size than the corner hollow cathode cavity; and
a second hollow cathode cavity is disposed at a location between the corner hollow cathode cavity and the first hollow cathode cavity, the second hollow cathode cavity is less in size than the corner hollow cathode cavity and less in size than the first hollow cathode cavity.

2. The gas distribution plate of claim 1, wherein the diffuser body is anodized.

3. The gas distribution plate of claim 1, wherein:
a second corner hollow cathode cavity is disposed near another corner, the second corner hollow cathode cavity is larger than the center hollow cathode cavity;
a third hollow cathode cavity is disposed at a location between the center hollow cathode cavity and the second corner hollow cathode cavity, the third hollow cathode cavity is greater in size than the center hollow cathode cavity and less in size than the second corner hollow cathode cavity; and
a fourth hollow cathode cavity is disposed at a location between the second corner hollow cathode cavity and the third hollow cathode cavity, the fourth hollow cathode cavity is less in size than the second corner hollow cathode cavity and less in size than the third hollow cathode cavity.

4. The gas distribution plate of claim 1, wherein the downstream surface has a plurality of concave portions.

5. The gas distribution plate of claim 4, wherein there are three concave portions.

6. A gas distribution plate, comprising:
a diffuser body having an upstream surface, a downstream surface, four sides and four corners, the diffuser body having a plurality of gas passages extending from the upstream surface to the downstream surface, each gas passage includes a hollow cathode cavity:
a center hollow cathode cavity is disposed near the center of the diffuser body;
a side hollow cathode cavity is disposed near the side of the diffuser body, the side hollow cathode cavity is larger than the center hollow cathode cavity;
a first hollow cathode cavity is disposed at a location between the center hollow cathode cavity and the side hollow cathode cavity, the first hollow cathode cavity is greater in size than the center hollow cathode cavity and less in size than the side hollow cathode cavity; and
a second hollow cathode cavity is disposed at a location between the side hollow cathode cavity and the first hollow cathode cavity, the second hollow cathode cavity is less in size than the side hollow cathode cavity and less in size than the first hollow cathode cavity.

7. The gas distribution plate of claim 6, wherein the diffuser body is anodized.

8. The gas distribution plate of claim 6, wherein:
a second side hollow cathode cavity is disposed near another side, the second side hollow cathode cavity is larger than the center hollow cathode cavity;
a third hollow cathode cavity is disposed at a location between the center hollow cathode cavity and the second side hollow cathode cavity, the third hollow cathode cavity is greater in size than the center hollow cathode cavity and less in size than the second side hollow cathode cavity; and
a fourth hollow cathode cavity is disposed at a location between the second side hollow cathode cavity and the third hollow cathode cavity, the fourth hollow cathode cavity is less in size than the second side hollow cathode cavity and less in size than the third hollow cathode cavity.

9. The gas distribution plate of claim 8, wherein:
a corner hollow cathode cavity is disposed near the corner of the diffuser body, the corner hollow cathode cavity is larger than the center hollow cathode cavity;
a fifth hollow cathode cavity is disposed at a location between the center hollow cathode cavity and the corner hollow cathode cavity, the fifth hollow cathode cavity is greater in size than the center hollow cathode cavity and less in size than the corner hollow cathode cavity; and
a sixth hollow cathode cavity is disposed at a location between the corner hollow cathode cavity and the fifth hollow cathode cavity, the sixth hollow cathode cavity is less in size than the corner hollow cathode cavity and less in size than the fifth hollow cathode cavity.

10. The gas distribution plate of claim 9, wherein:
a second corner hollow cathode cavity is disposed near another corner, the second corner hollow cathode cavity is larger than the center hollow cathode cavity;
a seventh hollow cathode cavity is disposed at a location between the center hollow cathode cavity and the second corner hollow cathode cavity, the seventh hollow cathode cavity is greater in size than the center hollow cathode cavity and less in size than the second corner hollow cathode cavity; and
an eighth hollow cathode cavity is disposed at a location between the second corner hollow cathode cavity and the seventh hollow cathode cavity, the eighth hollow cathode cavity is less in size than the second corner hollow cathode cavity and less in size than the seventh hollow cathode cavity.

11. The gas distribution plate of claim 6, wherein the downstream surface has a plurality of concave portions.

12. The gas distribution plate of claim 11, wherein there are three concave portions.

13. The gas distribution plate of claim 6, wherein:
a corner hollow cathode cavity is disposed near the corner of the diffuser body, the corner hollow cathode cavity is larger than the center hollow cathode cavity;
a third hollow cathode cavity is disposed at a location between the center hollow cathode cavity and the corner hollow cathode cavity, the third hollow cathode cavity is greater in size than the center hollow cathode cavity and less in size than the corner hollow cathode cavity; and
a fourth hollow cathode cavity is disposed at a location between the corner hollow cathode cavity and the third hollow cathode cavity, the fourth hollow cathode cavity is less in size than the corner hollow cathode cavity and less in size than the third hollow cathode cavity.

14. A plasma processing chamber, comprising:
a chamber body;
a substrate support disposed within the chamber body; and
a gas distribution plate disposed within the chamber body and facing the substrate support, the gas distribution plate comprising:
a diffuser body having an upstream surface, a downstream surface, four sides and four corners, the diffuser body having a plurality of gas passages extending from the upstream surface to the downstream surface, each gas passage includes a hollow cathode cavity:
a center hollow cathode cavity is disposed near the center of the diffuser body;
a comet hollow cathode cavity is disposed near the corner of the diffuser body, the corner hollow cathode cavity is larger than the center hollow cathode cavity;
a first hollow cathode cavity is disposed at a location between the center hollow cathode cavity and the corner hollow cathode cavity, the first hollow cathode cavity is greater in size than the center hollow cathode cavity and less in size than the corner hollow cathode cavity; and
a second hollow cathode cavity is disposed at a location between the corner hollow cathode cavity and the first hollow cathode cavity, the second hollow cathode cavity is less in size than the corner hollow cathode cavity and less in size than the first hollow cathode cavity.

15. The chamber of claim 14, wherein the diffuser body is anodized.

16. The chamber of claim 14, wherein:
a second corner hollow cathode cavity is disposed near another corner, the second corner hollow cathode cavity is larger than the center hollow cathode cavity;
a third hollow cathode cavity is disposed at a location between the center hollow cathode cavity and the second corner hollow cathode cavity, the third hollow cathode cavity is greater in size than the center hollow cathode cavity and less in size than the second corner hollow cathode cavity; and
a fourth hollow cathode cavity is disposed at a location between the second corner hollow cathode cavity arid the third hollow cathode cavity, the fourth hollow cathode cavity is less in size than the second corner hollow cathode cavity and less in size than the third hollow cathode cavity.

17. The chamber of claim 16, wherein:
a side hollow cathode cavity is disposed near a side of the diffuser body, the side hollow cathode cavity is larger than the center hollow cathode cavity;
a fifth hollow cathode cavity is disposed at a location between the center hollow cathode cavity and the side hollow cathode cavity, the fifth hollow cathode cavity is greater in size than the center hollow cathode cavity and less in size than the side hollow cathode cavity; and
a sixth hollow cathode cavity is disposed dt a location between the side hollow cathode cavity and the fifth hollow cathode cavity, the sixth hollow cathode cavity is less in size than the side hollow cathode cavity and less in size than the fifth hollow cathode cavity.

18. The chamber of claim 17, wherein the downstream surface has a plurality of concave portions.

19. The chamber of claim 14, wherein the downstream surface has a plurality of concave portions.

20. The chamber of claim 19, wherein there are at least three concave portions.
